(19) United States
(12) Patent Application Publication
(10) Pub. No.: US 2011/0158013 A1
(43) Pub. Date: Jun. 30, 2011

(54) FUSE SET OF SEMICONDUCTOR MEMORY AND REPAIR DETERMINATION CIRCUIT USING THE SAME

(75) Inventor: Ki Up KIM, Ichon-shi (KR)

(73) Assignee: Hynix Semiconductor Inc., Ichon-shi (KR)

(21) Appl. No.: 12/840,245

(22) Filed: Jul. 20, 2010

(30) Foreign Application Priority Data
Dec. 24, 2009 (KR) 10-2009-0130765

(51) Int. Cl. G11C 29/00; G11C 17/16

(52) U.S. Cl. 365/200; 365/225.7

(57) ABSTRACT

A fuse set of a semiconductor memory includes a first fuse array and a second fuse array each configured to designate a column redundancy address; and a unit fuse circuit configured to select one of the first fuse array and the second fuse array based on a row address.

### CROSS-REFERENCES TO RELATED APPLICATION

The present application claims priority under 35 U.S.C. § 119(a) to Korean Application No. 10-2009-0130765, filed on Dec. 24, 2009, in the Korean Intellectual Property Office, which is incorporated herein by reference in its entirety as if set forth in full.

### BACKGROUND

1. Technical Field

The present invention relates to a semiconductor memory, and more particularly, to a fuse set of a semiconductor memory and a repair determination circuit using the same.

2. Related Art

A semiconductor memory apparatus typically has redundant memory cells, redundant bit lines and redundant word lines for repairing memory cells, bit lines and word lines that have failed, for example, due to problems in manufacturing process.

A semiconductor memory apparatus may be also equipped with a repair determination circuit that stores information on a repaired address, determines whether an address designated from outside corresponds to an address to be repaired, and outputs the determination result.

A semiconductor memory apparatus typically controls its memory bank by dividing the memory bank into a plurality of zones. A memory bank is used as a unit for constituting a memory region.

FIG. 1 is a block diagram illustrating the structure of a typical memory bank. Referring to FIG. 1, one memory bank 1 may be divided into, for example, eight memory blocks, first through fourth quarter blocks Q0_U/Q0_D-Q3_U/Q3_D, each of which is divided into two memory blocks.

Such first through fourth quarter blocks Q0_U/Q0_D-Q3_U/Q3_D are defined by dividing one memory bank 1 into four blocks in a column direction and dividing each of the four blocks into an up block and a down block in a row direction.

While not shown in the figure, each of up blocks Q0_U-Q3_U and down blocks Q0_D-Q3_D of the first through fourth quarter blocks Q0_U/Q0_D-Q3_U/Q3_D includes a specific number of, e.g., (N+1) small regions in the column direction.

FIG. 2 is a block diagram of a typical fuse set circuit in a semiconductor memory apparatus. When a memory bank is structured as shown in FIG. 1, a typical repair determination circuit 10 may be configured as shown in FIG. 2.

Fuse set groups FSG_Q0-FSG_Q3 are respectively disposed for the first through fourth quarter blocks Q0_U/Q0_D-Q3_U/Q3_D.

Since the up block of the first quarter block Q0_U/Q0_D includes (N+1) small regions and the down block of the first quarter block Q0_U/Q0_D includes (N+1) small regions, the first quarter block Q0_U/Q0_D includes a total of 2(N+1) small regions. Accordingly, the fuse set group FSG_Q0 has 2(N+1) fuse sets FUSESET<0:N>_U and FUSESET<0:N>_D such that repair determination can be made for each of 2(N+1) small regions.

8(N+1) fuse sets 4*FUSESET<0:N>_U and 4*FUSESET<0:N>_D are needed to make a repair determination for the entire first through fourth quarter blocks Q0_U/Q0_D-Q3_U/Q3_D.

The fuse set groups FSG_Q0-FSG_Q3 compare the column redundancy addresses designated thereto with column addresses and output repair determination signals YRB_U<0:N> and YRB_D<0:N>.

In the repair determination signals YRB_U<0:N> and YRB_D<0:N>, one signal for the same numbered up blocks and one signal for the same numbered down blocks of the first through fourth quarter blocks Q0_U/Q0_D-Q3_U/Q3_D are combined through a NOR gate array 11, and the resultant repair determination signals YRB_Q<0:3><0:N> are outputted from the NOR gate array 11.

In the typical repair determination circuit 10 configured as mentioned above, since the 8(N+1) fuse sets are disposed for the first through fourth quarter blocks Q0_U/Q0_D-Q3_U/Q3_D, the fuse sets occupy a substantial area and consume significant amount of current.

### SUMMARY

In one embodiment of the present invention, a fuse set of a semiconductor memory includes: a first fuse array and a second fuse array each configured to designate a column redundancy address; and a unit fuse circuit configured to select one of the first fuse array and the second fuse array based on a row address.

In another embodiment of the present invention, a repair determination circuit of a semiconductor memory includes: a plurality of memory blocks; at least one fuse set corresponding to the plurality of memory blocks and configured to make a repair determination, wherein each fuse set is shared by two memory blocks.

In another embodiment of the present invention, a repair determination circuit of a semiconductor memory includes: a plurality of memory blocks, which are divided into first through fourth quarter blocks in a column direction, which in turn are divided into up blocks and down blocks in a row direction; and a plurality of fuse sets configured to make a repair determination, in correspondence to the plurality of memory blocks, wherein each fuse set is shared by one up is block and one down block in the same quarter block.

### BRIEF DESCRIPTION OF THE DRAWINGS

Features, aspects, and embodiments are described in conjunction with the attached drawings, in which:

FIG. 1 is a block diagram illustrating the structure of a typical memory bank;

FIG. 2 is a block diagram of a typical fuse set circuit;

FIG. 3 is a block diagram of a repair determination circuit in accordance with an embodiment of the present invention;

FIG. 4 is a block diagram illustrating the internal configuration of the fuse set shown in FIG. 3;

FIG. 5 is a circuit diagram of the unit fuse circuit shown in FIG. 4;

FIG. 6 is a circuit diagram of the address comparison section shown in FIG. 4; and

FIG. 7 is a circuit diagram of the determination section shown in FIG. 4.

### DETAILED DESCRIPTION

Hereinafter, a fuse set of a semiconductor memory and a repair determination circuit using the same according to the present invention will be described below with reference to the accompanying drawings through exemplary embodiments.

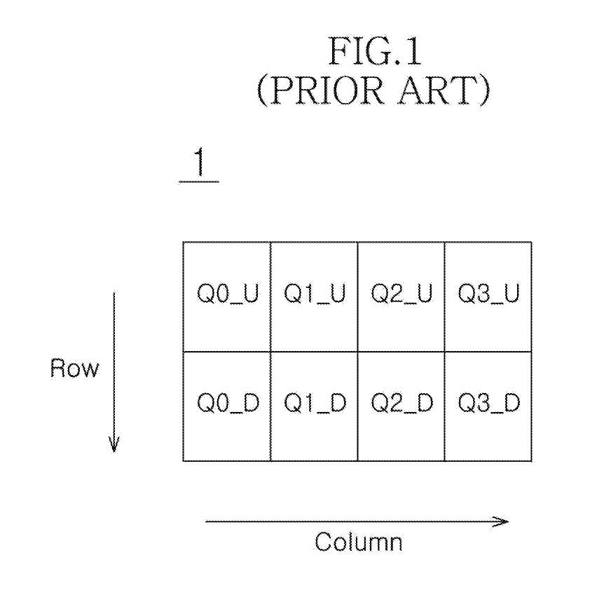

A repair determination circuit 100 in accordance with an embodiment of the present invention is exemplified to be configured based on a memory bank structure shown in FIG. 1.

First through fourth quarter blocks Q0_U/Q0_D-Q3_U/Q3_D are defined by dividing one memory bank 1 into four blocks in a column direction and dividing each of the four blocks into an up block and a down block in a row direction.

Each of up blocks Q0_U-Q3_U and down blocks Q0_D-Q3_D of the first through fourth quarter blocks Q0_U/Q0_D-Q3_U/Q3_D includes (N+1) small regions in the column direction (not shown).

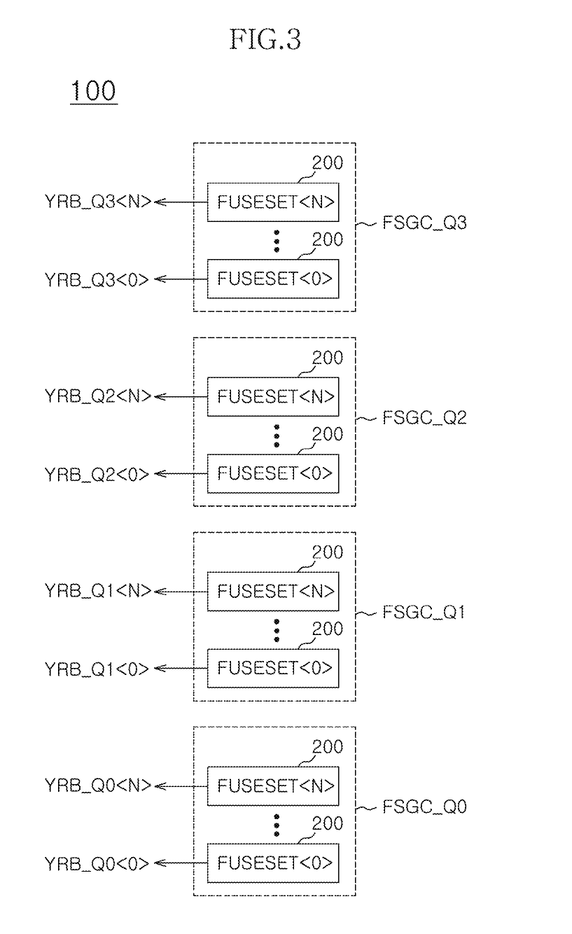

FIG. 3 is a block diagram of a repair determination circuit in accordance with an embodiment of the present invention. Referring to FIG. 3, the repair determination circuit 100 in accordance with the embodiment of the present invention includes fuse set groups FSGC_Q0-FSGC_Q3, which are disposed for the first through fourth quarter blocks Q0_U/Q0_D-Q3_U/Q3_D respectively.

The fuse set group FSGC_Q0 is disposed for the first quarter block Q0_U/Q0_D, the fuse set group FSGC_Q1 is disposed for the second quarter block Q1_U/Q1_D, the fuse set group FSGC_Q2 is disposed for the third quarter block Q2_U/Q2_D, and the fuse set group FSGC_Q3 is disposed for the fourth quarter block Q3_U/Q3_D.

Each of the first through fourth quarter blocks Q0_U/Q0_D-Q3_U/Q3_D includes 2(N+1) small regions ((N+1) small regions for the up block and (N+1) small regions for the down block), and each of the fuse set groups FSGC_Q0 through FSGC_Q3 includes (N+1) fuse sets FUSESET<0:N>.

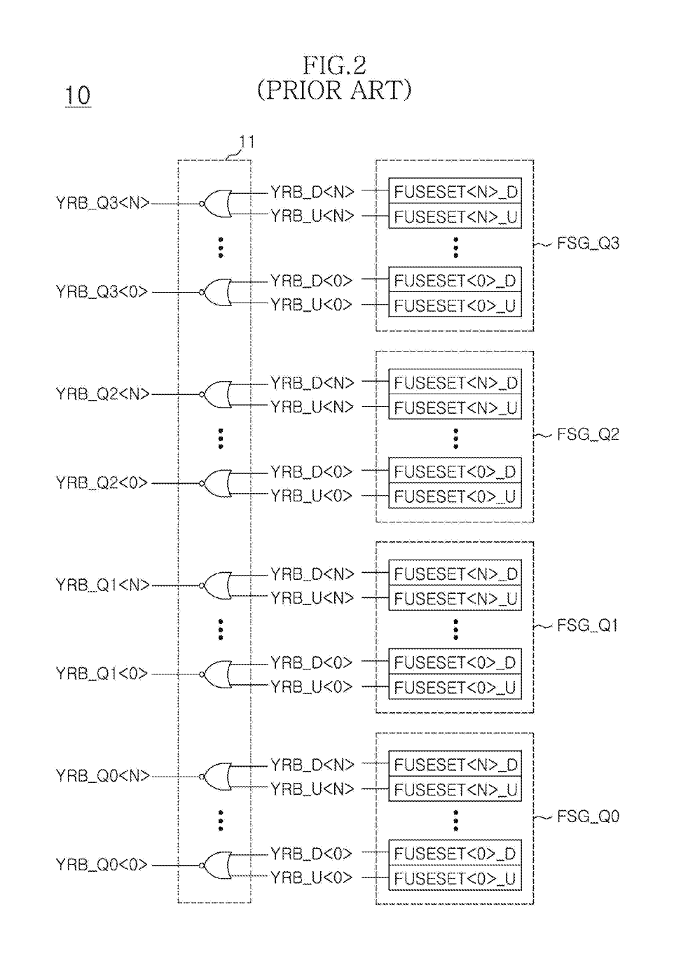

In accordance with an embodiment of the present invention, 4(N+1) fuse sets 4*FUSESET<0:N> are disposed for one memory bank—first through fourth quarter blocks Q0_U/Q0_D-Q3_U/Q3_D. In FIG. 2, 8(N+1) fuse sets 4*FUSESET<0:N>_U and 4*FUSESET<0:N>_D are needed for one memory bank.

In the repair determination circuit 100 in accordance with an embodiment of the present invention, the number of fuse sets for one memory bank is half the number of fuse sets for one memory bank in the typical semiconductor memory apparatus.

Therefore, the area occupied by the repair determination circuit 100 may be reduced, and current consumption can be decreased.

In the repair determination circuit 100 in accordance with an embodiment of the present invention, one fuse set can be shared by an up block and a down block, which are included in one quarter block. One fuse set can be shared by one small region of the up block and one small region of the corresponding down block, and the up block and the down block can be selected using a row address. Accordingly, the number of fuse sets can be decreased to half the number in the typical semiconductor memory apparatus.

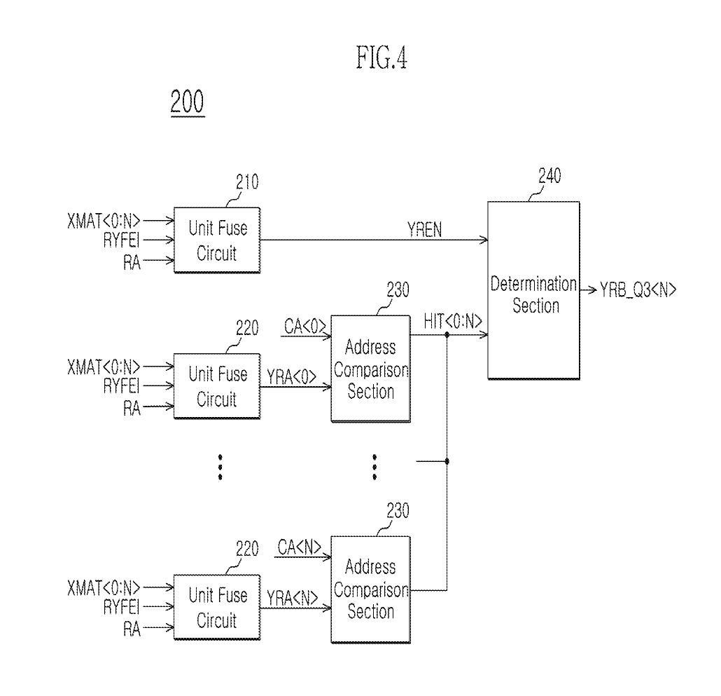

The (N+1) fuse sets FUSESET<0:N> thus configured will be described hereinafter. FIG. 4 is a block diagram illustrate fuse set shown in FIG. 3. Referring to FIG. 4, one fuse set FUSESET<N> includes a plurality of unit fuse circuits 210 and 220, a plurality of address comparison sections 230, and a determination section 240.

The unit fuse circuit 210 is configured to output a fuse set enable signal YREN for signaling the use of a fuse set circuit.

The plurality of unit fuse circuits 220 are configured to output a column redundancy address YRA<0:N> for any one of first and second memory regions in response to a row address RA.

The row address RA can use address bits from among an entire row of address bits, which divide the first through fourth quarter blocks Q0_U/Q0_D-Q3_U/Q3_D into up and down blocks.

The plurality of address comparison sections 230 are configured to compare the column redundancy address YRA<0:N> and a column address CA<0:N>, and output a comparison signal HIT<0:N>.

The determination section 240 is configured to output a repair determination signal YRB_Q3<N> based on the fuse set enable signal YREN and the comparison signal HIT<0:N>.

The plurality of unit fuse circuits 210 and 220 thus configured will be described hereinafter.

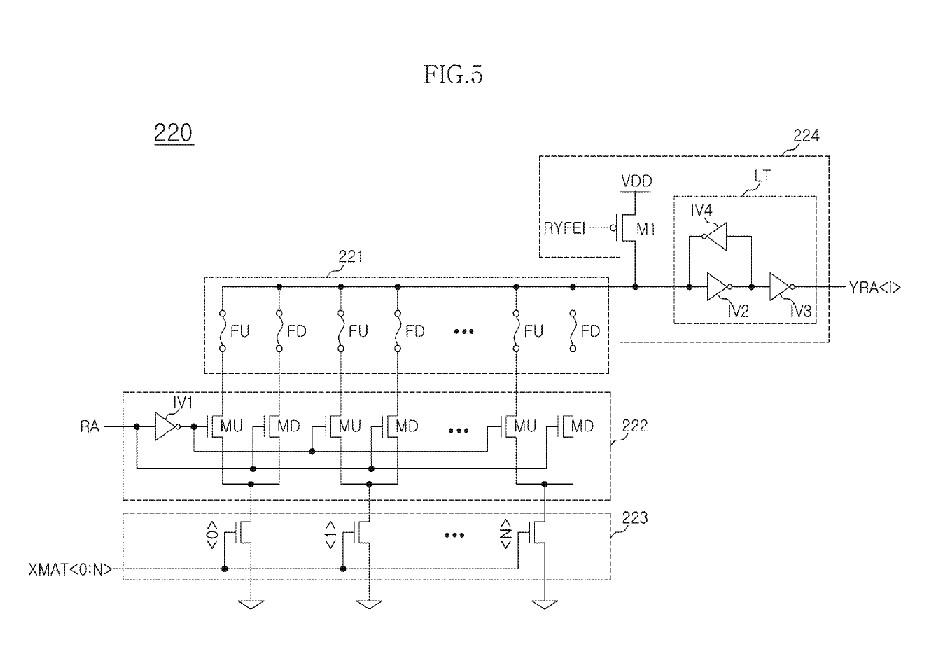

FIG. 5 is a circuit diagram of the unit fuse circuit shown in FIG. 4. Referring to FIG. 5, the unit fuse circuit 220 includes a fuse array part 221, a selection part 222, an activation part 223, and an initialization and latch part 224.

The fuse array part 221 includes a first fuse array FU and a second fuse array FD, which respectively correspond to one small region of the up block and one small region of the down block included in the quarter block.

For example, the first fuse array FU can correspond to the N^{th} small region of the up block Q0_U of the first quarter block, and the second fuse array FD can correspond to the N^{th} small region of the down block Q0_D of the first quarter block.

The selection part 222 is configured to select one of the first fuse array FU and the second fuse array FD based on the row address RA.

The selection part 222 includes an inverter IV1, a first transistor group MU, and a second transistor group MD.

The selection part 222 is configured in such a manner that the first transistor group MU is turned on when the row address RA has a low level and the second transistor group MD is turned on when the row address RA has a high level.

Where the row address RA has a low level, repair of the small region of the up block included in the quarter block can be determined, and in the case where the row address RA has a high level, repair of the small region of the down block included in the quarter block can be determined.

The activation part 223 is configured to couple the first transistor group MU or the second transistor group MD to a ground terminal based on an active signal XMAT<0:N> and thereby activate the unit fuse circuit 220. The activation part 223 has a plurality of transistors that are turned on based on the active signal XMAT<0:N>.

The active signal XMAT<0:N> is a signal that includes active information of unit cell arrays, or cell mats, divided in the row direction.

The initialization and latch section 224 includes a transistor M1, and a latch LT composed of a plurality of inverters IV2-IV4.

The initialization and latch section 224 is configured such that the transistor M1 initializes the column redundancy address YRA<i> to a high level based on a bank active information signal RYFEI and the column redundancy address YRA<i> is outputted through the latch LT. The bank active information signal RYFEI is a signal that has a high level in a bank active operation and has a low level in a precharge operation.

The plurality of address comparison sections 230 thus configured will be described hereinafter.

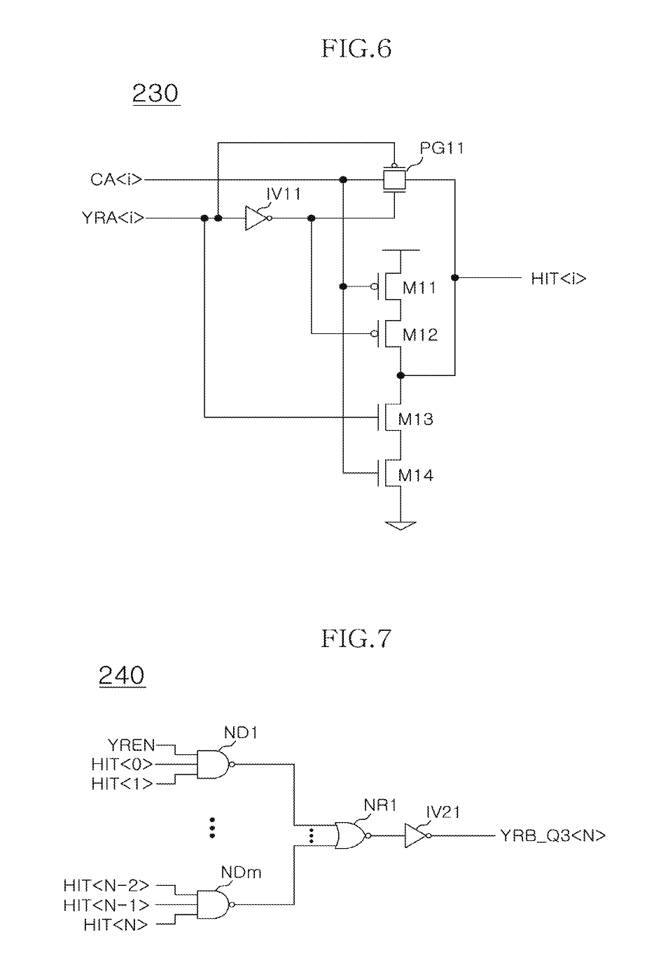

FIG. 6 is a circuit diagram of the address comparison section shown in FIG. 4. Referring to FIG. 6, the address comparison section 230 includes an inverter IV11, a pass gate PG11, and a plurality of transistors M11-M14.

The address comparison section 230 outputs the comparison signal HIT<i> to a high level when the column address CA<i> and the column redundancy address YRA<i> correspond to each other.

FIG. 7 is a circuit diagram of the determination section shown in FIG. 4. Referring to FIG. 7, the determination section 240 includes a plurality of NAND gates ND1-NDm, a NOR gate NR1, and an inverter IV21.

The determination section 240 outputs the repair determination signal YRB_Q3<N> to a low level when the fuse set is enable signal YREN and all bits of the comparison signal HIT<0:N> have high levels.

The determination section 240 outputs the repair determination signal YRB_Q3<N> to a high level when any one bit of the comparison signal HIT<0:N> has a low level.

Operations of the repair determination circuit 100 of a semiconductor memory in accordance with the embodiment of the present invention, configured as mentioned above, will be described below.

If a column fail while testing the semiconductor memory, a process for cutting the fuse of a corresponding column address is performed.

For example, suppose that a failure occurs in the column of the zeroth small region of the up block Q0_U of the first quarter block.

A column address corresponding to the zeroth small region of the up block Q0_U of the first quarter block is referred to as a first column address.

Accordingly, the fuses of the fuse set FUSESET<0> of the fuse set group FSGC_Q0, which are assigned to the zeroth small region of the up block Q0_U, are cut in correspondence to the first to column address.

Referring to FIG. 5, then, the first fuse arrays FU of the unit fuse circuits 220 of the fuse set FUSESET<0> of the fuse set group FSGC_Q0 are cut in correspondence to the first column address.

Also, the fuses of the unit fuse circuit 210 are also cut such that the fuse set enable signal YREN can be activated.

In another example, suppose that a failure occurs in each of the columns of the zeroth small region of the up block Q0_U of the first quarter block and the zeroth small region of the down block Q0_D of the first quarter block.

Column addresses corresponding to the zeroth small region of the up block Q0_U of the first quarter block and the zeroth small region of the down block Q0_D of the first quarter block are respectively referred to as a first column address and a second column address.

Accordingly, the fuses of the fuse set FUSESET<0> of the fuse set group FSGC_Q0, which are assigned to the zeroth small region of the up block Q0_U, and the fuses of the fuse set FUSESET<0> of the fuse set group FSGC_Q0, which are assigned to the zeroth small region of the down block Q0_D, are cut in correspondence to the first column address and the second column address.

Referring to FIG. 5, then, the first fuse arrays FU and the second fuse arrays FD of the unit fuse circuits 220 of the fuse set FUSESET<0> of the fuse set group FSGC_Q0 are cut in correspondence to the first column address and the second column address.

Also, the fuses of the unit fuse circuit 210 are also cut such that the fuse set enable signal YREN can be activated.

By cutting fuses in this way, referring to FIG. 5, the first is fuse arrays FU or the second fuse arrays FD are selected by the row address RA.

If the row address RA has a low level, the plurality of transistors MU of the selection part 222 are turned on and the first fuse arrays FU are selected, and if the row address RA has a high level, the plurality of transistors MD of the selection part 222 are turned on and the second fuse arrays FD are selected.

When the first fuse arrays FU are selected, the column redundancy address YRA<0:N> is outputted depending upon the fuse cutting states of the first fuse arrays FU corresponding to the active signal XMAT<0:N>.

Where the fuses of the first fuse arrays FU are cut in correspondence to the active signal XMAT<0:N>, the column redundancy address YRA<0:N> is maintained at an initial level, a high level, and where the fuses are not cut, the column redundancy address YRA<0:N> transitions to a low level.

The address comparison sections 230 activate the comparison signal HIT<0:N> when the column redundancy address YRA<0:N> and the column address CA<0:N> correspond to each other.

The determination section 240 activates the repair determination signal YRB_Q3<N> to a low level when both the comparison signal HIT<0:N> and the fuse set enable signal YREN have high levels.

If the repair determination signal TRB_Q3<N> is activated, is a column line corresponding to the column address is replaced with a redundancy column line.

As is apparent from the above description, in the embodiment of the present invention, different memory regions can share one fuse set by using a row address.

While the embodiment of the present invention has been described with reference to a memory bank that is composed in quarter blocks (each with up and down blocks), the present invention can be applied in the same manner where a memory bank is composed of half blocks.

While the four fuse set groups FSGC_Q0-FSGC_Q3 are provided in the case of the quarter blocks, the number of fuse set groups decreases to two in the case of half blocks, and each fuse set can be configured in the same way as shown in FIGS. 4-7.

While certain embodiments have been described above, it will be understood to those skilled in the art that the embodiments described are by way of example only. Accordingly, the fuse set of a semiconductor memory and the repair determination circuit using the same described herein should not be limited to the described embodiments. Rather, the fuse set of a semiconductor memory and the repair determination circuit using the same described herein should be considered in light of the claims that follow when taken in conjunction with the above description and accompanying drawings.

What is claimed is:

1. A fuse set of a semiconductor memory, comprising:
a first fuse array and a second fuse array each configured to designate a column redundancy address; and
a unit fuse circuit configured to select one of the first fuse array and the second fuse array based on a row address.

2. The fuse set according to claim 1, wherein the unit fuse circuit comprises:
a first transistor group coupled to the first fuse array and configured to operate based on an inverted row address of the row address; and
a second transistor group coupled to the second fuse array and configured to operate based on the row address.

3. The fuse set according to claim 2, further comprising:
an activation part configured to couple the first transistor group or the second transistor group to a ground terminal in response to an active signal, and activate the unit fuse circuit.

4. The fuse set according to claim 1, further comprising:
a plurality of address comparison sections configured to compare the column redundancy address and a column address, and output a comparison signal; and
a determination section configured to output a repair determination signal based on the outputted comparison signal.

5. The fuse set according to claim 4, wherein the address comparison sections are configured to activate the comparison signal when the column redundancy address and the column address correspond to each other.

6. The fuse set according to claim 4, wherein the determination section is configured to activate the repair determination signal when all bits of the comparison signal are activated.

7. A repair determination circuit of a semiconductor memory, comprising:
a plurality of memory blocks; and
at least one fuse set corresponding to the plurality of memory blocks and configured to make a repair determination,
wherein each fuse set is shared by two memory blocks.

8. The repair determination circuit according to claim 7, wherein each memory block is divided into at least two memory blocks in a column direction, and the memory blocks divided in the column direction are divided into up blocks and down blocks in a row direction.

9. The repair determination circuit according to claim 8, wherein the fuse set is configured to be shared by one up block and one down block of the same memory block.

10. The repair determination circuit according to claim 7, wherein the fuse set comprises:
a unit fuse circuit configured to select one of a first fuse array and a second fuse array according to a row address;
to a plurality of address comparison sections configured to compare a column redundancy address, designated by the first fuse array and the second fuse array, and a column address, and output a comparison signal; and
a determination section configured to output a repair determination signal according to the outputted comparison signal.

11. The repair determination circuit according to claim 10, wherein the unit fuse circuit comprises:
a first transistor group coupled to the first fuse array and configured to operate according to an inverted row address of the row address;
a second transistor group coupled to the second fuse array and configured to operate according to the row address; and
an activation part configured to couple the first transistor group or the second transistor group to a ground terminal in response to an active signal and activate the unit fuse circuit.

12. The repair determination circuit according to claim 10, wherein the address comparison section is configured to activate the comparison signal when the column redundancy address and the column address correspond to each other.

13. The repair determination circuit according to claim 10, wherein the determination section is configured to activate the repair determination signal when all bits of the comparison signal are activated.

14. A repair determination circuit of a semiconductor memory, comprising:
a plurality of memory blocks, which are divided into first through fourth quarter blocks in a column direction, which in turn are divided into up blocks and down blocks in a row direction; and
a plurality of fuse sets configured to make a repair determination, in correspondence to the plurality of memory blocks,
wherein each fuse set is shared by one up block and one down block in the same quarter block.

15. The repair determination circuit according to claim 14, wherein the fuse set comprises:
a unit fuse circuit configured to select one of a first fuse array and a second fuse array according to a row address;
a plurality of address comparison sections configured to compare one of column redundancy addresses, designated by the first fuse array and the second fuse array, and a column address, and output a comparison signal; and
a determination section configured to output a repair determination signal according to the outputted comparison signal.

16. The repair determination circuit according to claim 15, wherein the unit fuse circuit comprises:
a first transistor group coupled to the first fuse array and configured to operate according to an inverted row address of the row address;
a second transistor group coupled to the second fuse array and is configured to operate according to the row address; and
an activation part configured to couple the first transistor group or the second transistor group to a ground terminal in response to an active signal and activate the unit fuse circuit.

17. The repair determination circuit according to claim 15, wherein the address comparison section is configured to activate the comparison signal when the column redundancy address and the column address correspond to each other.

18. The repair determination circuit according to claim 15, wherein the determination section is configured to activate the repair determination signal when all bits of the comparison signal are activated.
